(19) United States
(12) Patent Application Publication
(10) Pub. No.: US 2012/0110401 A1
(43) Pub. Date: May 3, 2012

(54) SYSTEM AND METHOD OF SENSING DATA IN A SEMICONDUCTOR DEVICE

(75) Inventors: Seung Han RYU, Icheon-si (KR); Beom Ju SHIN, Icheon-si (KR); Jung Woo LEE, Seoul (KR); Myeong Woon JEON, Seoul (KR)

(73) Assignee: HYNIX SEMICONDUCTOR INC., Icheon-si (KR)

(21) Appl. No.: 12/983,122

(22) Filed: Dec. 31, 2010

(30) Foreign Application Priority Data
Oct. 29, 2010 (KR) 10-2010-0106808

(51) Int. Cl. G11C 29/04; G06F 11/22

(52) U.S. Cl. 714/721; 714/E11.145

(57) ABSTRACT

A semiconductor memory apparatus includes: a first data counting unit configured to count respective programming levels of a plurality of input data and output a plurality of first data counting codes having a code value corresponding to the number of respective programming levels; a data read unit configured to sense data stored in a memory block having the plurality of input data programmed therein, based on a voltage level of a plurality of read bias signals, and output the sensed result as a plurality of output data; a second data counting unit configured to count respective programming levels of the plurality of output data and output a plurality of second data counting codes having a code value corresponding to the number of respective programming levels; a read bias control unit configured to compare the plurality of first data counting codes with the plurality of second data counting codes and output a bias control code having a code value corresponding to the comparison result; and a read bias generating unit configured to generate the plurality of read bias signals whose voltage levels are adjusted based on the code value of the bias control code.

### CROSS-REFERENCES TO RELATED APPLICATION

The present application claims priority to Korean application number 10-2010-0106808, filed on Oct. 29, 2010, which is incorporated by reference in its entirety.

### BACKGROUND OF THE INVENTION

1. Technical Field

Embodiments relate to a semiconductor apparatus, and more particularly, to a technique for sensing data with reliability.

2. Related Art

A flash memory apparatus can be implemented with a multi-level cell (MLC) which stores multi-bit data in a single memory cell so as to improve integration density. That is, the MLC stores two or more bit data where a single level cell (SLC) stores one-bit data.

Therefore, the MLC storing 3-bit data has eight data distributions different from one another based on a programming level whereas the SLC has two data distributions different from each other based on a programming level.

Since the MLC is programmed to have a closer data distribution than the SLC, a data error probability is relatively higher when sensing the data stored in the MLC than when sensing the data stored in the SLC. A small amount of error can be corrected with an error correction code (ECC). However, since the amount of error that can be corrected with the ECC is limited, a technique capable of fundamentally reducing the data error probability is needed when sensing the data stored in the MLC.

### SUMMARY OF THE INVENTION

The embodiments of the present invention include a semiconductor memory apparatus, a semiconductor system and a method of sensing data, capable of efficiently reducing an error probability when sensing data stored in a memory cell.

In one embodiment of the present invention, a semiconductor memory apparatus includes: a first data counting unit configured to count respective programming levels of a plurality of input data and output a plurality of first data counting codes having a code value corresponding to the number of respective programming levels; a data read unit configured to sense data stored in a memory block having the plurality of input data programmed therein, based on a voltage level of a plurality of read bias signals, and output the sensed result as a plurality of output data; a second data counting unit configured to count respective programming levels of the plurality of output data and output a plurality of second data counting codes having a code value corresponding to the number of respective programming levels; a read bias control unit configured to compare the plurality of first data counting codes with the plurality of second data counting codes and output a bias control code having a code value corresponding to the comparison result; and a read bias generating unit configured to generate the plurality of read bias signals whose voltage levels are adjusted based on the code value of the bias control code.

In another embodiment of the present invention, a semiconductor memory apparatus includes: a first data counting unit configured to count respective programming levels of a plurality of input data and output a plurality of first data counting codes having a code value corresponding to the number of respective programming levels; a data read unit configured to sense data stored in a memory block having the plurality of input data programmed therein, based on a voltage level of a plurality of read bias signals, and output the sensed result as a plurality of output data; a second data counting unit configured to count respective programming levels of the plurality of output data and output a plurality of second data counting codes having a code value corresponding to the number of respective programming levels; a read bias control unit configured to store a look-up table wherein an offset voltage having a level corresponding to a code value difference between the plurality of first data counting codes and the plurality of second data counting codes, respectively, is predetermined, and adjust and output a code value of a bias control code based on the look-up table; and a read bias generating unit configured to generate the plurality of read bias signals whose voltage levels are adjusted based on the code value of the bias control code.

In still another embodiment of the present invention, a semiconductor system includes a memory controller and a semiconductor memory apparatus, wherein the semiconductor memory apparatus includes: a memory block wherein a plurality of input data are programmed with a programming level different from each other based on respective data values; a data read unit configured to sense data stored in the memory block, based on a voltage level of a plurality of read bias signals, and output the sensed result as a plurality of output data; and a read bias generating unit configured to generate the plurality of read bias signals whose voltage levels are adjusted based on a code value of a bias control code, and wherein the memory controller includes: a first data counting unit configured to count respective programming levels of the plurality of input data and output a plurality of first data counting codes having a code value corresponding to the number of respective programming levels; a second data counting unit configured to count respective programming levels of the plurality of output data and output a plurality of second data counting codes having a code value corresponding to the number of respective programming levels; and a read bias control unit configured to compare the plurality of first data counting codes with the plurality of second data counting codes and output the bias control code having the code value corresponding to the comparison result.

In still another embodiment of the present invention, a semiconductor system includes a memory controller and a semiconductor memory apparatus, wherein the semiconductor memory apparatus includes: a memory block wherein a plurality of input data are programmed with a programming level different from each other based on respective data values; a data read unit configured to sense data stored in the memory block, based on a voltage level of a plurality of read bias signals, and output the sensed result as a plurality of output data; and a read bias generating unit configured to generate the plurality of read bias signals whose voltage levels are adjusted based on a code value of a bias control code, and wherein the memory controller includes: a first data counting unit configured to count respective programming levels of the plurality of input data and output a plurality of first data counting codes having a code value corresponding to the number of respective programming levels; a second data counting unit configured to count respective programming levels of the plurality of output data and output a plurality of second data counting codes having a code value corresponding to the number of respective programming levels; and a read bias control unit configured to store a look-up table wherein an offset voltage having a level corresponding to a code value difference between the plurality of first data counting codes and the plurality of second data counting codes, respectively, is predetermined, and adjust and output the code value of the bias control code based on the look-up table.

In still another embodiment of the present invention, a data sensing method comprises: counting respective programming levels of a plurality of input data and generating a plurality of first data counting codes having a code value corresponding to the number of respective programming levels; sensing data stored in a memory block having the plurality of input data programmed therein, based on a voltage level of a plurality of read bias signals, and outputting the sensed result as a plurality of output data; counting respective programming levels of the plurality of output data and outputting a plurality of second data counting codes having a code value corresponding to the number of respective programming levels; comparing the plurality of first data counting codes with the plurality of second data counting codes and generating a bias control code having a code value corresponding to the comparison result; and generating the plurality of read bias signals whose voltage levels are adjusted based on the code value of the bias control code.

In still another embodiment of the present invention, a data sensing method comprises: counting respective programming levels of a plurality of input data and generating a plurality of first data counting codes having a code value corresponding to the number of respective programming levels; sensing data stored in a memory block having the plurality of input data programmed therein, based on a voltage level of a plurality of read bias signals, and outputting the sensed result as a plurality of output data; counting respective programming levels of the plurality of output data and outputting a plurality of second data counting codes having a code value corresponding to the number of respective programming levels; adjusting a code value of a bias control code based on a look-up table wherein an offset voltage having a level corresponding to a code value difference between the plurality of first data counting codes and the plurality of second data counting codes, respectively, is predetermined; and generating the plurality of read bias signals whose voltage levels are adjusted based on the code value of the bias control code.

### BRIEF DESCRIPTION OF THE DRAWINGS

Features, aspects, and embodiments are described in conjunction with the attached drawings, in which;

FIG. 1 is a first conceptual diagram showing a data sensing method according to an embodiment of the invention;

FIG. 2 is a second conceptual diagram showing a data sensing method according to an embodiment of the invention;

FIG. 3 is a diagram showing the number of data errors and a look-up table of FIG. 2;

FIG. 4 is a block diagram showing a configuration of a semiconductor system according to an embodiment of the invention; and

FIG. 5 is a diagram showing an internal operation of the semiconductor system of FIG. 4.

### DETAILED DESCRIPTION OF THE PREFERRED EMBODIMENTS

Hereinafter, preferred embodiments of the present invention will be described in detail with reference to the accompanying drawings so that the invention can easily be practiced by those skilled in the art to which the invention pertains. For reference, in drawings and detailed description, since the terms, symbols, marks and so on used to name devices, blocks and so on may be transcribed by detailed units according to needs, the same terms, symbols and marks may not name the same devices over circuits. Furthermore, data values of data signals may be differentiated according to a voltage level and a current magnitude and expressed in a single bit or multi bit form.

A semiconductor memory apparatus performs a programming operation with a programming level different from each other based on a data value of input data. That is, if the input data is one-bit data, the semiconductor memory apparatus is programmed with two programming levels based on a data value of the input data, thereby having two data distributions. In addition, if the input data is 3-bit data, the semiconductor memory apparatus is programmed with eight programming levels based on a data value of the input data, thereby having eight data distributions.

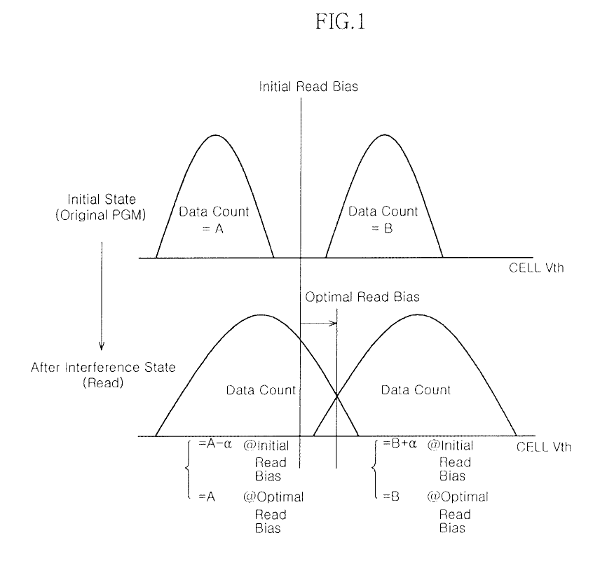

FIG. 1 is a first conceptual diagram showing a data sensing method according to the embodiment.

FIG. 1 shows a data distribution at an initial state where the input data is initially programmed and a data distribution at an interference state where interference between the data distributions occurs due to a noise, a coupling and the like.

The programmed level, i.e., the data value, is distinguished based on a voltage level of a read bias signal when sensing data stored in a memory cell. Since a voltage level of an initial read bias signal is interposed between a first data value distribution and a second data value distribution in the initial state, no error occurs even if the data is sensed based on the voltage level of the initial read bias signal assuming that the data distribution is continuously maintained. However, if the data is sensed based on the voltage level of the initial read bias signal when there is interference to the data distributions, a read error probability is severely increased.

Therefore, in an embodiment of the invention, a scheme of comparing the initial number of first and second data values with the number of first and second data values after the interference occurs and adjusting the voltage level of the read bias signal based on the comparison result is used, thereby decreasing probability of error. That is, if interference between the data distributions occurs, the data value is sensed based on a voltage level of an optimal read bias signal which is made by adding an offset voltage to the voltage level of the initial read bias signal.

Hereinafter, a scheme of adjusting the voltage level of the read bias signal will be described in detail with a more detailed exemplary embodiment.

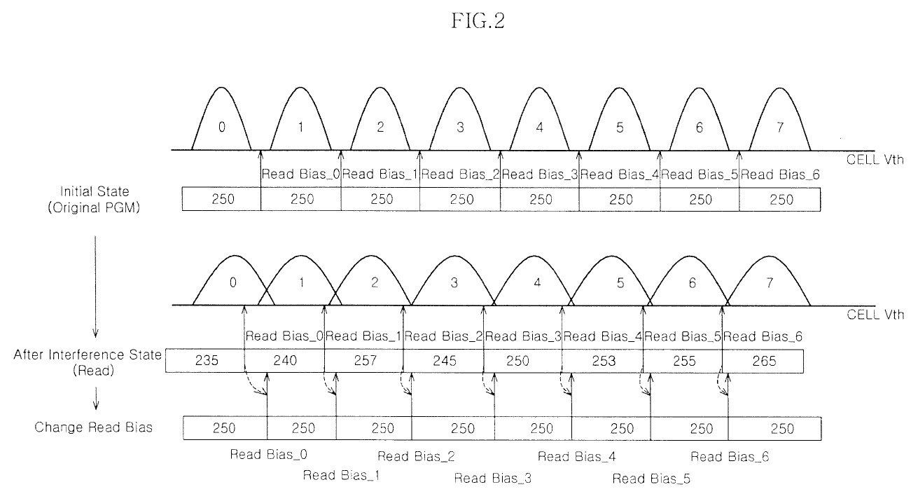

FIG. 2 is a second conceptual diagram showing a data sensing method according to the embodiment.

FIG. 2 shows a data distribution in an initial state where input data of a multi-bit form is programmed and a data distribution in an interference state where interference between the data distributions occurs due to a noise, a coupling and the like.

It is exemplified herein that each input data is 3-bit data. Therefore, as shown in FIG. 2, the semiconductor memory apparatus is programmed with eight programming levels based on a data value of the input data, and the programmed data forms eight data distributions. Therefore, in order to sense the respective data values which are classified into the eight programming levels, a total of seven read bias signals ‘Read Bias_0’ to ‘Read Bias_6’ are needed.

It is assumed that the 250 numbers data, respectively are distributed to first to eighth data value in the initial state. In the initial state, since a voltage level of the plurality of the read bias signals ‘Read Bias_0’ to ‘Read Bias_6’ is interposed between the data distributions of the first to eighth data values, respectively, no error occurs even if data is sensed based on the plurality of read bias signals ‘Read Bias_0’ to ‘Read Bias_6’ assuming that the data distribution is continuously maintained. However, if the data is sensed based on the initial read bias signals ‘Read Bias_0’ to ‘Read Bias_6’ when interference between the data distributions occurs like in the interference state, an error probability is severely increased. At this time, if the data is sensed based on the initial read bias signals ‘Read Bias_0’ to ‘Read Bias_6’ in the interference state, an error occurs due to the interference and thereby the 250 numbers data, respectively are not distributed to first to eighth data values, as shown in FIG. 2. Therefore, in the embodiment, an error probability is decreased with a scheme of comparing the initial number of the first to eighth data values with the number of the first to eighth data values after the interference occurs and adjusting respective voltage levels of the plurality of read bias signals ‘Read Bias_0’ to ‘Read Bias_6’ based on the comparison result. That is, if the interference between the data distributions occurs like in the interference state, the data value is sensed based on respective read bias signals ‘Read Bias_0’ to ‘Read Bias_6’ whose voltage levels are adjusted such that an offset voltage is added to the respective voltage levels of the initial read bias signals ‘Read Bias_0’ to ‘Read Bias_6’. The offset voltage may have a minus voltage level or a plus voltage level. In view of reducing the error probability, respective voltage levels of all of the read bias signals ‘Read Bias_0’ to ‘Read Bias_6’ may be adjusted independently.

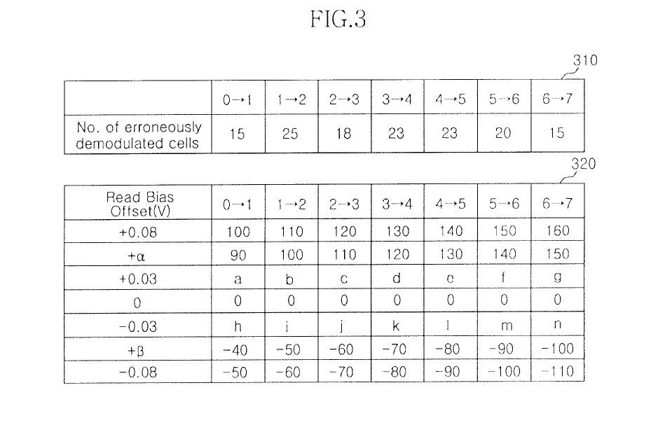

FIG. 3 is a diagram showing the number of data errors and a look-up table of FIG. 2.

FIG. 3 shows the number of data errors (Table 310) where the interference between the data distributions occurs like in the interference state of the embodiment of FIG. 2 but the data is sensed based on the initial read bias signals ‘Read Bias_0’ to ‘Read Bias_6’. In addition, FIG. 3 shows a look-up table (Table 320) where an offset voltage which has a level corresponding to a difference between the initial number of the first to eighth data values and the number of the first to eighth data values after the interference occurs, respectively, is predetermined. That is, in the embodiment, a scheme of adjusting the respective voltage levels of the read bias signals ‘Read Bias_0’ to ‘Read Bias_6’ by as much as the offset voltage, based on the predetermined look-up table 320, can be used.

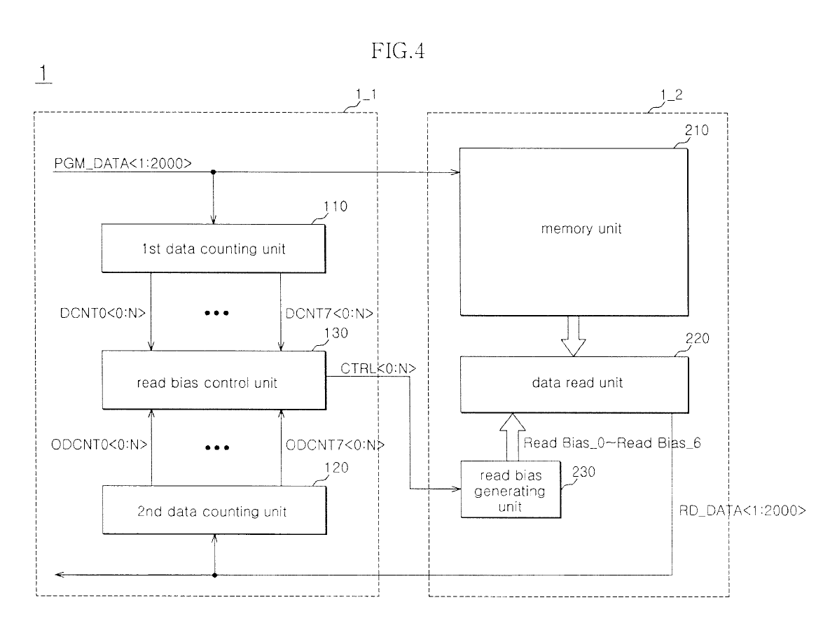

FIG. 4 is a block diagram showing a configuration of a semiconductor system 1 according to an embodiment of the invention.

The semiconductor system 1 in accordance with the present embodiment of the invention includes only a simplified configuration for the sake of clear description.

Referring to FIG. 4, the semiconductor system 1 includes a memory controller 1_1 and a semiconductor memory apparatus 1_2.

The semiconductor memory apparatus 1_2 includes a memory unit 210, a data read unit 220, and a read bias generating unit 230.

The memory unit 210 is divided into a plurality of memory blocks and each of the plurality of memory blocks is composed of a plurality of memory cells. In this embodiment, it is assumed that the memory cell is a flash memory cell which is a representative nonvolatile memory cell.

The semiconductor memory apparatus 1_2 performs a programming operation with a programming level based on a data value of input data, and stores the input data in the memory block. Therefore, in the memory block, a plurality of input data ‘PGM_DATA<1:2000>’ are programmed with a programming level based on the respective data values.

The data read unit 220 senses data stored in the memory block based on a voltage level of the plurality of read bias signals ‘Read Bias_0’ to ‘Read Bias_6’, and outputs the sensed result as a plurality of read data ‘RD_DATA<1:2000>’.

The read bias generating unit 230 generates the plurality of read bias signals ‘Read Bias_0’ to ‘Read Bias_6’ whose voltage levels are adjusted based on a code value of bias control codes ‘CTRL<0: N>’.

In addition, the memory controller 1_1 includes a first data counting unit 110, a second data counting unit 120, and a read bias control unit 130.

The first data counting unit 110 counts respective programming levels of the plurality of input data ‘PGM_DATA<1:2000>’, and outputs a plurality of first data counting codes ‘DCNT0<0:N>’ to ‘DCNT7<0:N>’ having a code value corresponding to the number of respective programming levels.

The second data counting unit 120 counts respective programming levels of the plurality of read data ‘RD_DATA<1:2000>’, and outputs a plurality of second data counting codes ‘ODCNT0<0:N>’ to ‘ODCNT7<0:N>’ having a code value corresponding to the number of respective programming levels.

The read bias control unit 130 compares the plurality of first data counting codes ‘DCNT0<0:N>’ to ‘DCNT7<0:N>’ with the plurality of second data counting codes ‘ODCNT0<0:N>’ to ‘ODCNT7<0:N>’, and outputs bias control codes ‘CTRL<0:N>’ having the code value corresponding to the comparison result.

Meanwhile, the read bias control unit 130 can be configured in various ways according to various implementations. For example, the read bias control unit 130 can be configured to compare the plurality of first data counting codes ‘DCNT0<0:N>’ to ‘DCNT7<0:N>’ with the plurality of second data counting codes ‘ODCNT0<0:N>’ to ‘ODCNT7<0:N>’ until the plurality of first data counting codes ‘DCNT0<0:N>’ to ‘DCNT7<0:N>’ and the plurality of second data counting codes ‘ODCNT0<0:N>’ to ‘ODCNT7<0:N>’ match, and generate the bias control codes ‘CTRL<0:N>’ having the code value corresponding to the comparison result. In this exemplary configuration, the number of errors can be reduced to minimum, but a total of data sensing time can be somewhat increased as repetition times are increased.

The read bias control unit 130 can also be configured to compare the plurality of first data counting codes ‘DCNT0<0:N>’ to ‘DCNT7<0:N>’ with the plurality of second data counting codes ‘ODCNT0<0:N>’ to ‘ODCNT7<0:N>’ up to a predetermined time, and generate the bias control codes ‘CTRL<0:N>’ having the code value corresponding to the comparison result. In this exemplary configuration, the data sensing time can be substantially prevented from being too large because the repetition times are limited to the predetermined time.

The read bias control unit 130 can also be configured to compare at least one of the plurality of first data counting codes ‘DCNT0<0:N>’ to ‘DCNT7<0:N>’ with at least one of the plurality of second data counting codes ‘ODCNT0<0:N>’ to ‘ODCNT7<0:N>’, and generate the bias control codes ‘CTRL<0:N>’ having the code value corresponding to the comparison result. In this exemplary configuration, the representative data values where many errors occur are compared with each other, and only the corresponding read bias signals ‘Read Bias_0’ to ‘Read Bias_6’ are adjusted.

The read bias control unit 130 can also be configured to store a predetermined look-up table. That is, in the look-up table, an offset voltage corresponding to a code value difference between the plurality of first data counting codes ‘DCNT0<0:N>’ to ‘DCNT7<0:N>’ and the plurality of second data counting codes ‘ODCNT0<0:N>’ to ‘ODCNT7<0:N>’, respectively, is predetermined, and the read bias control unit 130 adjusts and outputs the code value of the bias control codes ‘CTRL<0:N>’ based on the look-up table. In this exemplary configuration, optimal bias control codes ‘CTRL<0:N>’ can be determined through only one comparison operation by using the look-up table optimized beforehand.

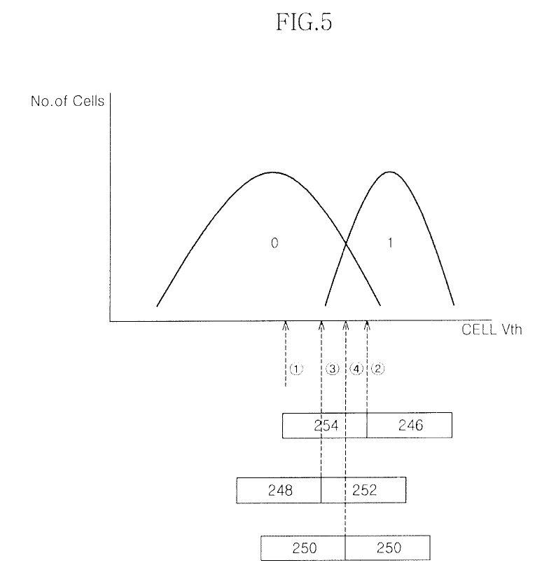

FIG. 5 is a diagram showing an internal operation of the semiconductor system of FIG. 4.

FIG. 5 shows an example where an optimal read bias signal ‘Read Bias_i’ is generated through a repetitive comparison operation.

In FIG. 5, a first read bias signal (refer to 1) shows a voltage level of an initial read bias signal. A second read bias signal (refer to 2) is adjusted to have a higher voltage level than the voltage level of the first read bias signal (refer to 1). A third read bias signal (refer to 3) is adjusted to have a lower voltage level than the voltage level of the second read bias signal (refer to 2). Finally, after repeating the above-mentioned operation, an optimal voltage level of a fourth read bias signal (refer to 4) is determined.

For reference, although the semiconductor system 1 is configured such that the memory controller 11 and the semiconductor memory apparatus 1_2 are combined into a single system, the semiconductor system 1 can also be implemented with a semiconductor memory apparatus having a system-on-chip (SOC) configuration if the first data counting unit 110, the second data counting unit 120, and the read bias control unit 130 included in the memory controller 1_1 are all included in the semiconductor memory apparatus 1_2 in order to improve an integration density and performance.

As described above, a data sensing method comprises: counting respective programming levels of a plurality of input data and generating a plurality of first data counting codes having a code value corresponding to the number of respective programming levels; sensing data stored in a memory block having the plurality of input data programmed therein, based on a voltage level of a plurality of read bias signals, and outputting the sensed result as a plurality of output data; counting respective programming levels of the plurality of output data and outputting a plurality of second data counting codes having a code value corresponding to the number of respective programming levels; comparing the plurality of first data counting codes with the plurality of second data counting codes and generating a bias control code having a code value corresponding to the comparison result; and generating a plurality of read bias signals whose voltage levels are adjusted based on the code value of the bias control code.

In addition, a data sensing method comprises: counting respective programming levels of a plurality of input data and generating a plurality of first data counting codes having a code value corresponding to the number of respective programming levels; sensing data stored in a memory block having the plurality of input data programmed therein, based on a voltage level of a plurality of read bias signals, and outputting the sensed result as a plurality of output data; counting respective programming levels of the plurality of output data and outputting a plurality of second data counting codes having a code value corresponding to the number of respective programming levels; adjusting a code value of a bias control code based on a look-up table where an offset voltage having a level corresponding to a code value difference between the plurality of first data counting codes and the plurality of second data counting codes, respectively, is predetermined; and generating a plurality of read bias signals whose voltage levels are adjusted based on the code value of the bias control code.

While certain embodiments have been described above, it will be understood to those skilled in the art that the embodiments described are by way of example only. Accordingly, the device and method described herein should not be limited based on the described embodiments. Rather, the apparatus described herein should only be limited in light of the claims that follow when taken in conjunction with the above description and accompanying drawings.

What is claimed is:

1. A semiconductor memory apparatus configured to perform a programming operation with a programming level based on a data value of input data, comprising:
a first data counting unit configured to count a first number of respective programming levels of a plurality of input data and output a plurality of first data counting codes having a code value corresponding to the first number of respective programming levels;
a data read unit configured to sense data stored in a memory block having the plurality of input data programmed therein, based on a voltage level of a plurality of read bias signals, and output the sensed result as a plurality of output data;
a second data counting unit configured to count a second number of respective programming levels of the plurality of output data and output a plurality of second data counting codes having a code value corresponding to the second number of respective programming levels;
a read bias control unit configured to compare the plurality of first data counting codes with the plurality of second data counting codes and output a bias control code having a code value corresponding to the comparison result; and
a read bias generating unit configured to generate the plurality of read bias signals whose voltage levels are adjusted based on the code value of the bias control code.

2. The semiconductor memory apparatus of claim 1, wherein the input data is configured to be multi-bit data.

3. The semiconductor memory apparatus of claim 1, wherein the read bias control unit is configured to compare the plurality of first data counting codes with the plurality of second data counting codes until the plurality of first data counting codes and the plurality of second data counting codes match.

4. The semiconductor memory apparatus of claim 1, wherein the read bias control unit is configured to compare the plurality of first data counting codes with the plurality of second data counting codes up to a predetermined time.

5. The semiconductor memory apparatus of claim 1, wherein the read bias control unit is configured to compare at least one of the plurality of first data counting codes with at least one of the plurality of second data counting codes.

6. A semiconductor memory apparatus configured to perform a programming operation with a programming level based on a data value of input data, comprising:
a first data counting unit configured to count a first number of respective programming levels of a plurality of input data and output a plurality of first data counting codes having a code value corresponding to the first number of respective programming levels;
a data read unit configured to sense data stored in a memory block having the plurality of input data programmed therein, based on a voltage level of a plurality of read bias signals, and output the sensed result as a plurality of output data;
a second data counting unit configured to count a second number of respective programming levels of the plurality of output data and output a plurality of second data counting codes having a code value corresponding to the second number of respective programming levels;
a read bias control unit configured to store a look-up table wherein an offset voltage having a level corresponding to a code value difference between the plurality of first data counting codes and the plurality of second data counting codes, respectively, is predetermined, and adjust and output a code value of a bias control code based on the look-up table; and
a read bias generating unit configured to generate the plurality of read bias signals whose voltage levels are adjusted based on the code value of the bias control code.

7. The semiconductor memory apparatus of claim 6, wherein the input data is configured to be multi-bit data.

8. A semiconductor system comprising a memory controller and a semiconductor memory apparatus,
wherein the semiconductor memory apparatus includes:
a memory block wherein a plurality of input data are programmed with a programming level based on respective data values;
a data read unit configured to sense data stored in the memory block, based on a voltage level of a plurality of read bias signals, and output the sensed result as a plurality of output data; and
a read bias generating unit configured to generate the plurality of read bias signals whose voltage levels are adjusted based on a code value of a bias control code, and
wherein the memory controller includes:
a first data counting unit configured to count a first number of respective programming levels of the plurality of input data and output a plurality of first data counting codes having a code value corresponding to the first number of respective programming levels;
a second data counting unit configured to count a second number of respective programming levels of the plurality of output data and output a plurality of second data counting codes having a code value corresponding to the second number of respective programming levels; and
a read bias control unit configured to compare the plurality of first data counting codes with the plurality of second data counting codes and output the bias control code having the code value corresponding to the comparison result.

9. The semiconductor system of claim 8, wherein the input data is configured to be multi-bit data.

10. The semiconductor system of claim 8, wherein the read bias control unit is configured to compare the plurality of first data counting codes with the plurality of second data counting codes until the plurality of first data counting codes and the plurality of second data counting codes match.

11. The semiconductor system of claim 8, wherein the read bias control unit is configured to compare the plurality of first data counting codes with the plurality of second data counting codes up to a predetermined time.

12. The semiconductor system of claim 8, wherein the read bias control unit is configured to compare at least one of the plurality of first data counting codes with at least one of the plurality of second data counting codes.

13. A semiconductor system comprising a memory controller and a semiconductor memory apparatus,
wherein the semiconductor memory apparatus includes:
a memory block wherein a plurality of input data are programmed with a programming level based on respective data values;
a data read unit configured to sense data stored in the memory block, based on a voltage level of a plurality of read bias signals, and output the sensed result as a plurality of output data; and
a read bias generating unit configured to generate the plurality of read bias signals whose voltage levels are adjusted based on a code value of a bias control code, and
wherein the memory controller includes:
a first data counting unit configured to count a first number of respective programming levels of the plurality of input data and output a plurality of first data counting codes having a code value corresponding to the first number of respective programming levels;
a second data counting unit configured to count a second number of respective programming levels of the plurality of output data and output a plurality of second data counting codes having a code value corresponding to the second number of respective programming levels; and
a read bias control unit configured to store a look-up table wherein an offset voltage having a level corresponding to a code value difference between the plurality of first data counting codes and the plurality of second data counting codes, respectively, is predetermined, and adjust and output the code value of the bias control code based on the look-up table.

14. The semiconductor system of claim 13, wherein the input data is configured to be multi-bit data.

15. A data sensing method comprising:
counting a first number of respective programming levels of a plurality of input data and generating a plurality of first data counting codes having a code value corresponding to the first number of respective programming levels;
sensing data stored in a memory block having the plurality of input data programmed therein, based on a voltage level of a plurality of read bias signals, and outputting the sensed result as a plurality of output data;
counting a second number of respective programming levels of the plurality of output data and outputting a plurality of second data counting codes having a code value corresponding to the second number of respective programming levels;
comparing the plurality of first data counting codes with the plurality of second data counting codes and generating a bias control code having a code value corresponding to the comparison result; and
generating the plurality of read bias signals whose voltage levels are adjusted based on the code value of the bias control code.

16. The method of claim 15, wherein generating the bias control code comprises comparing the plurality of first data counting codes with the plurality of second data counting codes until the plurality of first data counting codes and the plurality of second data counting codes match.

17. The method of claim 15, wherein generating the bias control code comprises comparing the plurality of first data counting codes with the plurality of second data counting codes up to a predetermined time.

18. The method of claim 15, wherein generating the bias control code comprises comparing at least one of the plurality of first data counting codes with at least one of the plurality of second data counting codes.

19. A data sensing method comprising:
counting a first number of respective programming levels of a plurality of input data and generating a plurality of first data counting codes having a code value corresponding to the first number of respective programming levels;
sensing data stored in a memory block having the plurality of input data programmed therein, based on a voltage level of a plurality of read bias signals, and outputting the sensed result as a plurality of output data;
counting a second number of respective programming levels of the plurality of output data and outputting a plurality of second data counting codes having a code value corresponding to the second number of respective programming levels;
adjusting a code value of a bias control code based on a look-up table wherein an offset voltage having a level corresponding to a code value difference between the plurality of first data counting codes and the plurality of second data counting codes, respectively, is predetermined; and
generating the plurality of read bias signals whose voltage levels are adjusted based on the code value of the bias control code.
